(19) United States
(12) Patent Application Publication
(10) Pub. No.: US 2025/0131326 A1
(43) Pub. Date: Apr. 24, 2025

(54) OPTIMIZING LOSSY COMPRESSION FOR BLACK-BOX CLASSIFICATION MODELS WITH LABEL-LESS DATA

(71) Applicant: Dell Products L.P., Round Rock, TX (US)

(72) Inventors: Rômulo Teixeira de Abreu Pinho, Niterói (BR); Vinicius Michel Gottin, Rio de Janeiro (BR); Paulo de Figueiredo Pires, Niterói (BR); Alex Laier Bordignon, Niterói (BR); Franklin Jordan Ventura Quico, Niterói (BR); João Victor Daher Daibes, Niterói (BR)

(21) Appl. No.: 18/493,042

(22) Filed: Oct. 24, 2023

(51) Int. Cl. G06N 20/00; H03M 7/30

(52) U.S. Cl. CPC G06N 20/00; H03M 7/6011

(57) ABSTRACT

Optimizing lossy compression for classification models with unlabeled data is disclosed. In determining a compression quality, a global KL divergence threshold for input data is determined. If a divergence between the KL divergence of data and perturbed data is less than the global KL divergence threshold, a classifier will perform within a percentage of its original accuracy. A relationship between the compression quality \hat{q}nd the KL divergences of the compressed and decompressed data, after being processed by the classifier is determined. An optimal compression quality is determined based on the global KL divergence threshold and the relationship.

### FIELD OF THE INVENTION

Embodiments of the present invention generally relate to compressing data that is transmitted for use by machine learning models. More particularly, at least some embodiments of the invention relate to systems, hardware, software, computer-readable media, and methods for determining an acceptable compression quality for data that is subsequently classified in a machine learning model.

### BACKGROUND

Machine learning models can be trained for a variety of purposes including classifying data. More specifically, a classifier, which is a type of machine learning model, can be trained to classify data into one or more learned classes or categories. Once the model is trained, new data may be input to the trained model and the model may generate an output that assigns the data to one of the learned classes or categories. There are scenarios, however, where it may be necessary to compress and decompress the data prior to providing the input data to the classifier. This may lead to increased error in the classifications performed by the classifier. More specifically, when data is compressed using lossy compression techniques, the decompressed data is different from the original data. As a result, the ability of a classifier to correctly classify the data may be reduced.

The use of data compression techniques is a common practice to reduce bandwidth consumption during data transmission for classification models. Conventionally, the compression rate or compression quality is determined using empirical techniques. Empirical techniques, however, require a deep understanding of the classification model and may require multiple iterations with different compression qualities to evaluate the impact of compression on the model's accuracy.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings, in which:

FIG. 1 discloses aspects of a computing environment or system in which a compression quality for data is determined and implemented during execution of an application such as classifying input data;

FIG. 2 discloses aspects of an example method for determining a compression quality or level while ensuring adequate classifier accuracy;

FIGS. 3A and 3B disclose additional aspects of an example method for determining a compression quality or level while ensuring adequate classifier accuracy;

FIG. 4 discloses aspects of experimental results;

FIG. 5 discloses aspects of curves describing a relation between an average KL divergence and compression quality; and

FIG. 6 discloses aspects of a computing device, system, or entity.

### DETAILED DESCRIPTION OF SOME EXAMPLE EMBODIMENTS

Embodiments of the present invention generally relate to machine learning models including classifiers configured to classify or categorize input data. More particularly, at least some embodiments of the invention relate to systems, hardware, software, computer-readable media, and methods for determining a compression quality for data such that a classifier can still classify the data without significant loss in accuracy.

For example, a classification model (e.g., a classifier) may operate in a computing environment such as a cloud system. In order to classify data, the data is transmitted to the classifier. The data may be, by way of example, time series data, image data, audio data, video data, or other data including vector data. An image classifier, for example, may operate to classify image data.

When the number of inferences to be performed is large, throughput is limited, or for other reasons, the data may be compressed using lossy compression techniques prior to being transmitted to the classifier. The compression quality may be difficult to determine, particularly when the classifier is a black box classifier. A classifier is a black box classifier when the manner in which the classifier operates is not known or only partially known. For example, the weights of the classifier may be unknown or unavailable.

By way of example, embodiments of the invention relate to scenarios where a black box classifier is available for inferences and the input data is compressed. Embodiments of the invention consider several scenarios. In a first scenario, a training dataset is available with known labels (known classifications or categories). In this scenario, the accuracy of the classifier model can be correlated with the level of compression. As a result, an acceptable compression quality Docket No: 16192.904 can be correlated to an acceptable loss in accuracy. In a second scenario, an input dataset does not have labels and this prevents the correlation performed in the first scenario.

Embodiments of the invention may be configured to determine limits to the amount of perturbation that can be applied to input data without significantly impacting the classification results output by the classifier. Embodiments determine these limits considering the model outputs and the input data or a sample of the input data.

Embodiments of the invention may also be configured to determine a compression parameter. The compression parameter allows compression to be controlled to an amount that maintains sufficient accuracy in the outputs of the classifier. For example, the compression parameter may be set to maintain 95% or 90% accuracy of the classifier.

In one example, embodiments of the invention can determine acceptable compression levels based on an analytical analysis of KL (Kullback-Leibler) divergences between the inference of the original data and the inference of the decompressed data. This allows the compression quality to be assessed without consulting the labels of the data or the model weights directly. This also provides flexibility in determining the compression quality in various use cases. Embodiments of the invention allow a user to determine how much accuracy to sacrifice in order to compress the input data to be classified.

Thus, embodiments of the invention relate to determining a compression quality of input data while maintaining an acceptable classifier accuracy. When submitting data to black box models, compression qualities or levels may be determined using a sample of the input data and without the need for labels.

Embodiments of the invention may be employed in scenarios such as cloud-based model execution, where it may be beneficial to conserve bandwidth. Bandwidth can be conserved by performing lossy compression on the data being transmitted. For example, an application may use data generated by smart sensors. The data generated by the sensors may be transmitted to an edge system or a cloud system for classification. Embodiments of the invention may determine a compression quality to target, for example, a 5% loss in model accuracy compared to the uncompressed original data.

Embodiments of the invention may sample the input data, use the outputs (e.g., classifications) generated by the model, and determine a compression quality or level that will maintain sufficient model accuracy.

More specifically, embodiments of the invention estimate a variation in KL divergence (a maximum KL divergence in one example). This allows embodiments of the invention to evaluate how a perturbation in the input data will affect the classification of a black-box classifier. Embodiments of the invention are advantageously used in scenarios where data is subject to lossy compression and may also be used in scenarios where the data is subject to interference, such as sound capture through microphones or image capture quality. Thus, lossy compression and interference may be examples of perturbations to the input data.

Through embodiments of the invention, the necessary quality of sensors for certain tasks can be evaluated. Engineering processes can be improved because embodiments of the invention can be used to identify cost-effective equipment for specific tasks. For example, some microphones are better at capturing sound data or handling interference. The data quality of data generated, which reflects perturbations to the data, by these different microphones may vary and may be further impacted by compression operations. Embodiments of the invention may be used to identify the quality of microphone required for a given task based on acceptable losses in the original data, whether due to interference or compression. In order to maintain 95% accuracy in a model given a particular compression technique, a certain quality of hardware is required.

Embodiments of the invention can determine compression qualities or levels such that the accuracy of classifiers, or other black-box models, maintain a predefined percentage of their original accuracy. The ability to control compression levels while maintaining sufficient model accuracy allows the bandwidth used to deliver the data to the model to be optimized and enables bandwidth savings.

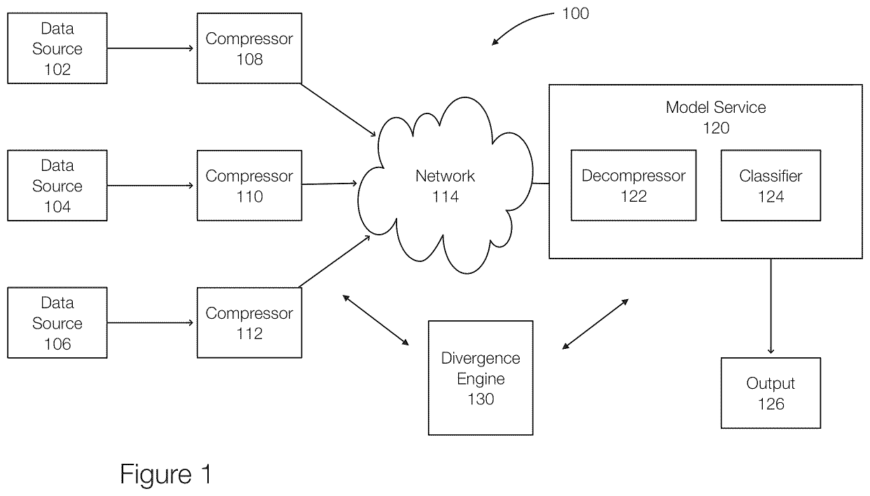

FIG. 1 discloses aspects of setting or determining compression qualities or levels while maintaining sufficient model accuracy. FIG. 1 illustrates a model service 120 that includes a classifier 124 and that may provide a variety of different models including various classifiers to customers. The classifier 124 is an example of a model that has learned to classify or categorize data. In this example, the classifier 124 is configured to classify data generated by one or more of the data sources 102, 104, and 106. The data generated by the data sources 102, 104, and 106 may be sensor data, video data, audio data, image data, or other data type.

For various reasons (e.g., conserve bandwidth), the data generated by the data sources 102, 104, and 106 may be compressed by, respectively, compressors 108, 110, ad 112 prior to transmission over a network 114. In this example, lossy compression techniques may be performed. When the data is compressed and transmitted to the model service 120, the model service 120 may decompress the compressed data with a decompressor 122 prior to inputting the data into the classifier 124. The classifier 124 generates an output 126 for each data. The output 126 may be a category. More generally, the output 126 is a probability distribution and the category assigned to the data may be inferred or determined from the distribution.

As previously stated, compressing the data at the compressors 108, 110, and 112 is typically lossy. As a result, the data received as input to the classifier 124 is different from the data output by the data sources 102, 104, and 106. This impacts the accuracy of the classifier 124.

Embodiments of the invention include a divergence engine 130, which may be associated with the data sources, the model service 120, or the like. The divergence engine 130 may operate at the data sources 102, 104, and 106 (or other client), the model service 120, or independently. The divergence engine 130 is configured to determine a compression quality or level while maintaining an acceptable classifier accuracy.

Generally, the divergence engine 130 is configured to determine a compression quality that allows bandwidth to be conserved without impacting the accuracy of the classifier 124 by more than a predetermined amount. For example, the compression quality or level may be set that that the model loses no more than 5% accuracy, or 10% accuracy. These parameters can be user defined and may be dynamic based on conditions of the network 114. Thus, the compression level may increase if latency is too long or for other reasons. The compression level may also adapt to a current accuracy of the classifier 124.

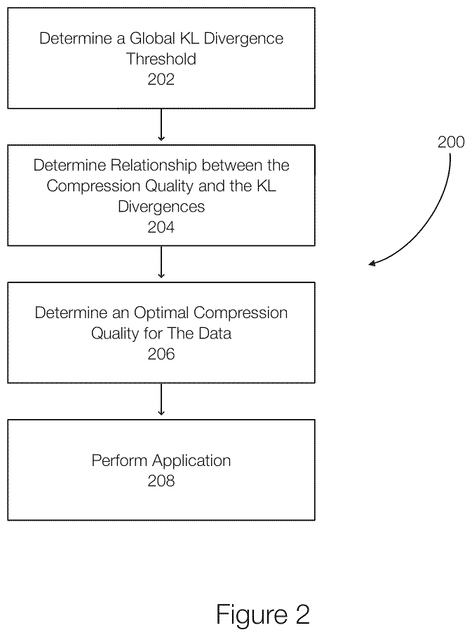

FIG. 2 discloses aspects of a method for determining a compression quality or level while ensuring adequate classifier accuracy. The method 200 initially determines 202 a global KL divergence threshold. In one example, an input data X and a classifier f(X) are available. A global KL divergence threshold Lₖₗ(X,f) is determined to ensure that if the data X is perturbed (e.g., lossy compression, interference), the KL divergence between the input data X and the perturbed data X are below global divergence threshold. The classifier is expected to perform at least at T percent of its original accuracy. In this example, T is a tolerance parameter (e.g., T=95%).

Once the global KL divergence threshold 202 is determined, a relationship between the compression quality \hat{q}nd the KL divergences generated between the compressed and decompressed data after being processed by the classifier f(X) is determined.

An optimal compression quality for the data is then determined 206. More specifically, using the global divergence threshold and the relationship (in terms of KL divergences in one example) between the compressed and decompressed data after being processed by the classifier, an optimal compression quality \hat{q} for the input data may be determined 206.

An application is then performed 208 using the optimal compression quality. For example, data generated by a data source may be compressed based on the optimal compression quality \hat{q}nd transmitted to a classifier for classification.

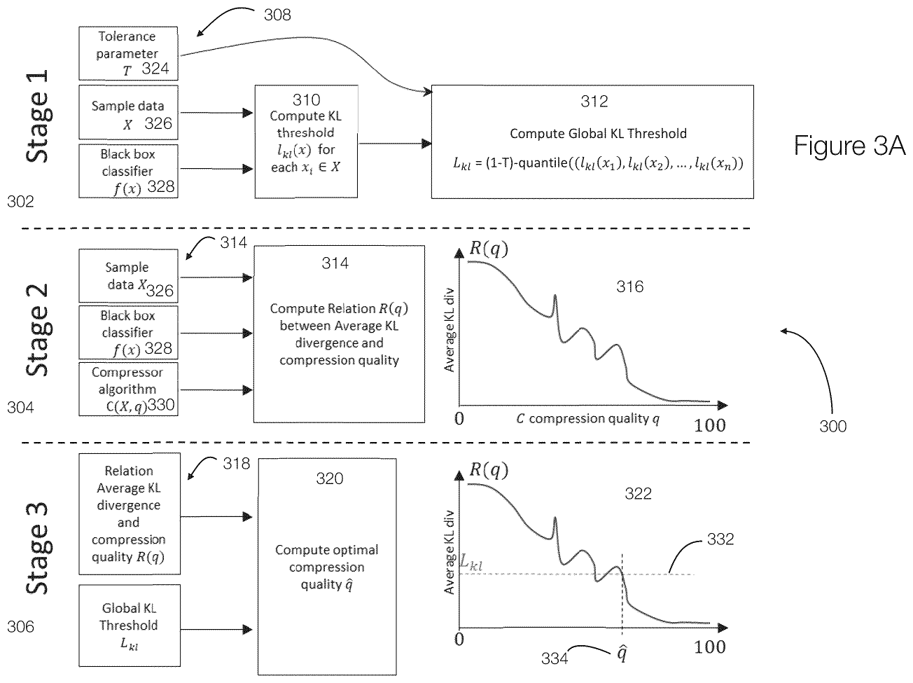

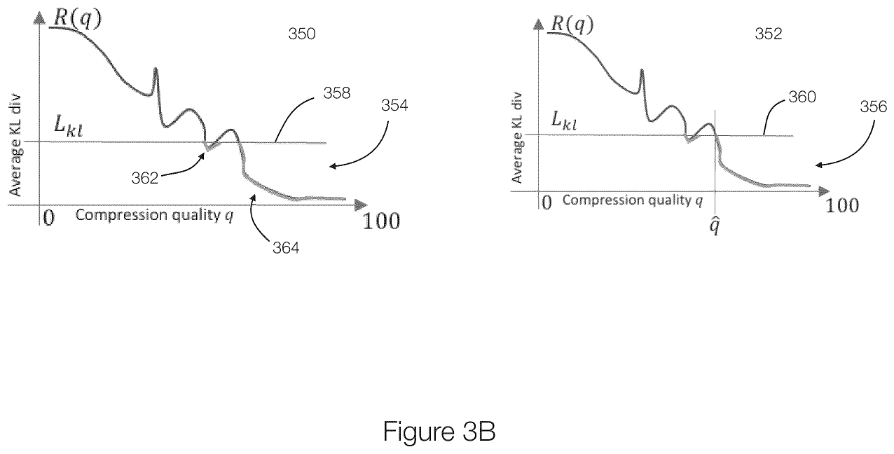

FIGS. 3A and 3B discloses additional aspects of an example method for determining a compression quality or level while ensuring adequate classifier accuracy. FIG. 3A illustrates a method 300, which is an example of the method 200 in FIG. 2. The method 300 is illustrated in stages 302, 304, and 306. Stage 302 initiates the process of determining a compression quality for an application using, by way of example, three inputs. The stage 302 includes or receives, as inputs 308, a tolerance parameter T 324, sample data X 326, and a classifier f(X) 328, which may be a black box classifier.

The sample data 326 is a sample of the input data to be classified by the classifier 328. More specifically, the sample data 326 may be a sample matrix where each row of the sample matrix (xᵢ, i=1, 2, . . . , n) represents a sample of the original input data (or input matrix) and n is the total number of samples from the input data.

The classifier 328, for a sample x, outputs a vector of size equal to c. In this example, c is the number of classes of the classifier 328, and the vector output by the classifier includes the probabilities of x belonging to each of the possible classes.

A numerical tolerance parameter 324 represents the percentage of accuracy in relation to the original data to be maintained when compressing the input data. For example, when the tolerance parameter 324 is 95% (e.g., T=95%), 95% of the original classifier accuracy should be maintained when compressing the data. Embodiments of the invention operate to determine the compression quality to achieve at least this level of model accuracy.

In the stage 302, an individual KL threshold of each sample is calculated (lₖₗ(xᵢ)). The individual KL threshold of a sample is determined by first calculating a probability vector f(xᵢ)=[p₁, p₂, . . . , p_{c}], where c is the number of elements in the probability vector. The two largest elements from this vector are referred to as q₁ and q₂.

The individual KL threshold is defined as:

$${l}_{k l} ( {x}_{i} ) = kl ( [ {q}_{1} , {q}_{2} ] , [ {q}_{1} - \frac{d}{2} , {q}_{2} + \frac{d}{2} ] ) .$$

In this example, d=q₂−q₁ and kl refers to the Kullback-Leibler divergence. In one example, \tilde{x}ᵢ may be any perturbation made to the vector xᵢ. If

$$k l ( f ( {x}_{i} ) , f ( {\tilde{x}}_{i} ) ) < {l}_{k l} ( {x}_{i} ) ,$$

then the classifier 328 classifies both xᵢ and \tilde{x}ᵢ in the same class. This is because kl is a monotonically increasing function when the first entry is fixed.
In one example, [lₖₗ(xᵢ), i=1,2, . . . , n] is a vector of the local kl values for all samples. This allows a global KL threshold Lₖₗ(X, f) to be defined, in one example, as follows:

$${L}_{k l} ( X , f ) = ( 1 - T ) - percentile {l}_{k l} ( {x}_{i} ) , i = 1 , 2 , … , n .$$

This example illustrates that if input data X is perturbed in an arbitrary way to generate perturbed data \tilde{X}, the classifier 328 is expected to maintain the class of T—percent of the samples from the input data X with respect to the perturbed data X, if the perturbation satisfies the following conditions in one example:

$$k l ( f ( {x}_{i} ) , f ( {\tilde{x}}_{i} ) ) < {L}_{k l} ( X , f ) , i = 1 , 2 , … , n .$$

Thus, in the stage 302, the individual KL threshold for each sample in the sample data 326 is computed 310. This allows the global KL threshold to be computed 312 and completes the stage 302 in one example embodiment.

The stage 304 establishes or determines a relation between an average KL divergence and compression quality. Different compressors may be associated with different compression qualities. The inputs 314 in stage 304 include the sample data 326, the classifier 328, and the compressor 330. In this example, a compression algorithm (the compressor 330) may be represented as a function C(X, q). The compressor 330 receives a data matrix X (e.g., the sample data 326) and a quality parameter \hat{q} as input. An approximation \tilde{X}=C(X, q) of the matrix X is generated after the compression and decompression processes. The approximation \tilde{X} represents the decompressed data after being compressed at a given compression quality q. In this example, q ∈ [1,100], where 100 represents high compression quality \hat{q}nd 1 represents low compression quality.

A function R(q) relates the compression quality \hat{q} of a compressor C 330 to the average of the KL divergences obtained from the classification of the original data X and the classification of the decompressed data \tilde{X}=C(X, q). The function R(q) is computed 3145 or defined as follows in one example:

$$R ( q ) = Average ( kl ( f ( {x}_{i} ) , f ( {\tilde{x}}_{i} ) ) , i = 1 , 2 , … n ) .$$

In this example, xᵢ is the i-th sample from X, and \tilde{x}ᵢ is the i-th decompressed sample from \tilde{X}=C(X, q). In one example, R(q) outputs a real number. As the value of q increases, the perturbation of the data is smaller, the divergences become smaller, and the value of R(q) generally decreases. The relation between the average KL divergence and the compression quality is illustrated in the plot 316 of the function R(q).

Thus, given a compressor C (e.g., compressor 330), a classifier f (e.g., classifier 328), and a sample X (e.g., sample data 326), the relationship between the average KL divergences of the classification of the original data f(X) and classification of the decompressed data f(X) for each compression quality value between 1 and 100. The plot 316 illustrates the general behavior of R(q) for given C, f and X.

In one example, in order to generate R(q), it is necessary to compress the sample data 326, decompress the sample data 326, and pass the decompressed data through the classifier 328. This is performed, in one example, multiple times, once for each value of q (e.g., 100 times when q ∈ [1,100]).

The time required to perform these aspects of the stage 304 may depend on the classifier 328, the compressor 330, and the number of samples in the sample data 326. The time required to perform the stage 304 can be reduced by reducing the size of the sample data 326 or reducing the sampling of quality points q. When the sampling of quality points is reduced, the value of R(q) is approximated.

As illustrated in FIG. 3, the stage 302 generates a global KL threshold 312 [symbol] Lₖₗ [symbol] and the stage 304 generates a relation R(q). In the stage 306, these serve as input 318 to determine an optimal quality value q for the compressor 330 such that T % of the decompressed samples are classified in the same class as the uncompressed original data.

Initially, the values of q for which R(q)<Lₖₗ are determined as illustrated in the plot 322. The values where R(q)<Lₖₗ are shown below the dashed line 332 in the plot 322, which is the same as the plot 316. To determine an optimal value a, the smallest possible value that ensures that R(q) is below the KL threshold is identified. That value is identified as follows:

$$\hat{q} = min ( x ) subject to R ( q ) < {L}_{kl} for all x < q , with x ∈ [ 1 , 100 ] .$$

An example value is \hat{q} 334 is illustrated in the plot 322.

In one example, the value of q for a given input data is determined and a compression with quality \hat{q} is applied to new data. In order to maintain accuracy, the new samples should respect the distribution of the sample data used in determining the compression quality value. However, this assumption is generally necessary for a classifier to maintain accuracy consistent with its training data.

Once a compression quality is determined, the input data may be transmitted using the compression quality. the accuracy of the classifier can be monitored to ensure that the application is achieving the desired classifier accuracy. If necessary, the compression quality can be reevaluated periodically, redetermined using new sample data, or the like. This may be performed as the characteristics of the input data may change over time.

FIG. 3B discloses aspects of R(q) in more detail. The plot 350 illustrates values 354 where R(q)<Lₖₗ are below the line 358. The plot 352 similarly illustrates values 356 where R(q)<Lₖₗ are below the line 360. However, the optimal value of \hat{q}, in one example, ensures that R(q) is below the KL threshold. The values 362 in the plot 350 do not provide this assurance because higher values of \hat{q} in the plot 350 are above the threshold represented by the line 358. Thus, the value of \hat{q}, selected is illustrated as the value 334 (see FIG. 3A).

### Experiments

Experiments were performed on three datasets: arrow, MNIST, and WISDM, using three types of classification models: MLP, SVM, and Logistic Regression, and three compression algorithms: DCT, Jpeg, and RLTC. A total of 21 experiments were conducted by combining a dataset with a classification model and a compression algorithm.

For all experiments, the same methodology was followed. First, the samples were divided into training and testing sets, with 50% of the data used for training and 50% of the data used for testing. The training data was used to generate the classification model and to estimate the optimal compression quality \hat{q}. The parameter T was the same for all experiments: T=95%.

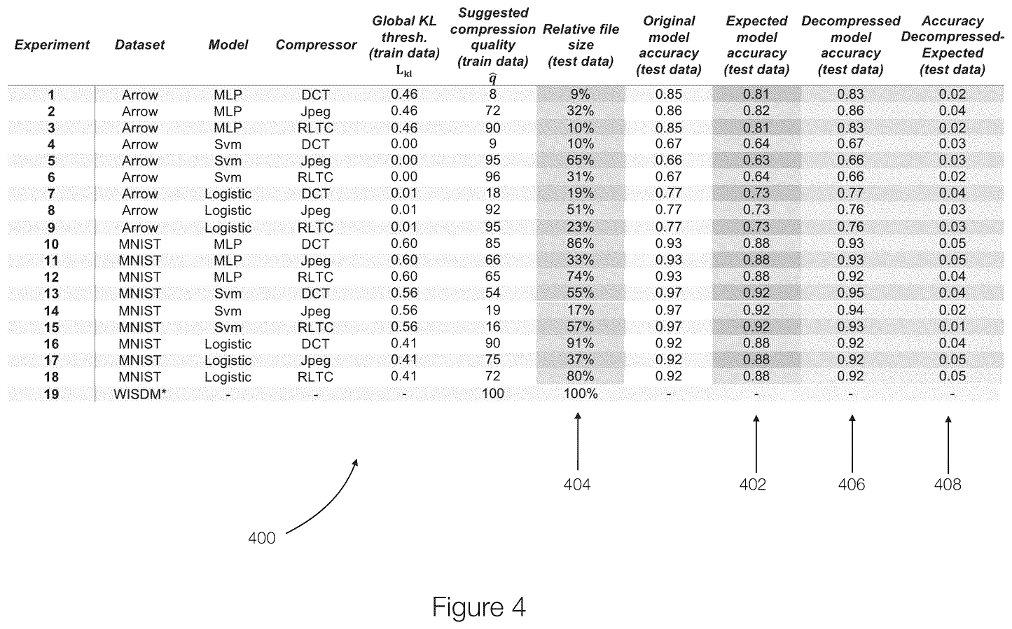

FIG. 4 discloses aspects of experimental results. The table 400, more specifically, illustrates results obtained in the experiments. In the table 400, the values in the column 402 are target baseline values. The data in the columns 404, 406, and 408 illustrate results obtained by embodiments of the invention and illustrate gains over the baseline values in the column 402. The experimental results for the WISDM* dataset (row 19) are excluded from the table 400 as embodiments of the invention suggested no compression was advisable in that experiment.

The dataset column indicates the name of the dataset used and the model and compressor columns indicate the type of classifier and compression algorithm used, respectively, in the experiment. The Global KL threshold column displays the value of the Global KL threshold (Lₖₗ) obtained in phase 302, using only the training data.

The suggested compression quality column shows the value of \hat{q}obtained in the phase 304 using only the training data. In one example, the ‘compression quality’ refers to the parametrization of the compression algorithm, defined as values between 1 and 100; with 100 corresponding to maximum quality (no compression) and 1 corresponding to minimum quality (maximum compression).

The relative file size column represents the relative size of the compressed test data when applying the compression algorithm with quality \hat{q}.

The original model accuracy column displays the accuracy of the model on the test data, while the expected model accuracy column shows the expected accuracy of the model when applied to the compressed data with quality \hat{q}, i.e., T=95% of the original accuracy of the model applied to the uncompressed data.

The decompressed model accuracy column shows the accuracy of the model applied to the test data after compression and decompression.

The accuracy column (Decompressed-Difference) highlights the difference between the obtained accuracy value and the expected value.

Analyzing the results presented in the table 400, embodiments of the invention can generate a compression quality where the accuracy loss is very close to the parameter T=95% of original accuracy.

In these experiments, the average absolute difference between the expected value and the obtained value, displayed in the last column of the table 400, has an average of 0.03. This indicates that the method performed as expected for these experiments, and that the proposed compression parameter \hat{q} is a very good parameter for compression.

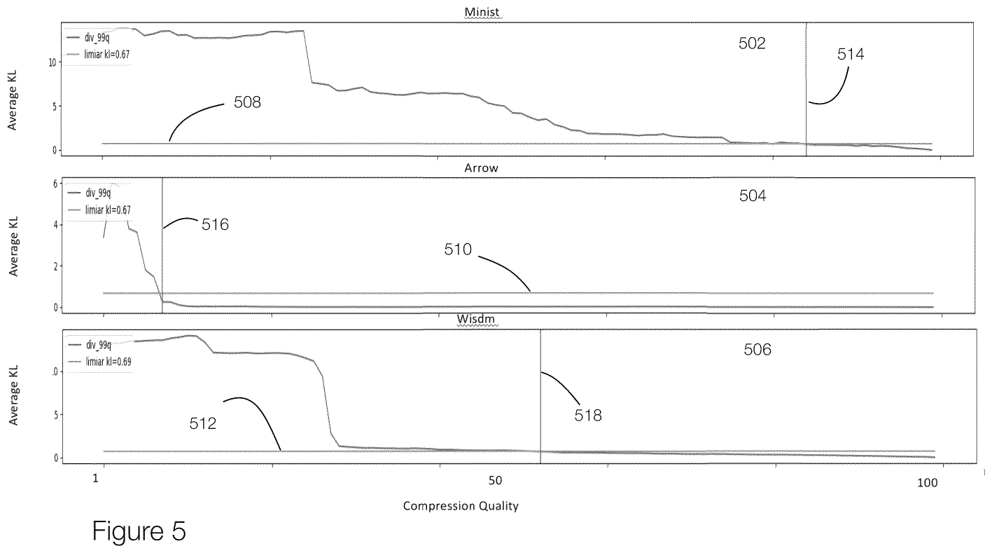

FIG. 5 discloses aspects of real R(q) curves 502, 504, and 506 for, respectively, experiments 1, 10, and 19 in the table 400. The lines 508, 510, and 512 are the global KL threshold for each of the experiments and the lines 514, 516, and 518 represent the value of \hat{q}determined for the respective curves 502, 504, and 506.

In these examples, the error increases or decreases depending on whether the test data respects the same distributions as the training data.

Embodiments of the invention suggest no compression (a compression quality of 100) for the WISDM dataset as illustrated in row 19 of the table 400. The experiment of row 19, as illustrated in the curve 506, indicated that any compression of this dataset prevented the selected classifiers from classifying the complex dataset with sufficient accuracy. As a result, embodiments of the invention can accurately identify that no compression is recommended without incurring an unacceptable loss of accuracy for the classifier model.

The appendix, incorporated by reference, provides additional information about the datasets and classification models used in the foregoing experiments.

It is noted that embodiments of the invention, whether claimed or not, cannot be performed, practically or otherwise, in the mind of a human. Accordingly, nothing herein should be construed as teaching or suggesting that any aspect of any embodiment of the invention could or would be performed, practically or otherwise, in the mind of a human. Further, and unless explicitly indicated otherwise herein, the disclosed methods, processes, and operations, are contemplated as being implemented by computing systems that may comprise hardware and/or software. That is, such methods processes, and operations, are defined as being computer-implemented.

The following is a discussion of aspects of example operating environments for various embodiments of the invention. This discussion is not intended to limit the scope of the invention, or the applicability of the embodiments, in any way.

In general, embodiments of the invention may be implemented in connection with systems, software, and components, that individually and/or collectively implement, and/or cause the implementation of, compression operations, decompression operations, classification or other machine learning operations, compression quality selection operations, model accuracy maintaining operations, and the like. More generally, the scope of the invention embraces any operating environment in which the disclosed concepts may be useful.

New and/or modified data collected and/or generated in connection with some embodiments, may be stored in a data storage environment that may take the form of a public or private cloud storage environment, an on-premises storage environment, and hybrid storage environments that include public and private elements. Any of these example storage environments, may be partly, or completely, virtualized. The storage environment may comprise, or consist of, a datacenter which is operate to perform various operations initiated by one or more clients or other elements of the operating environment.

Example cloud computing environments, which may or may not be public, include storage environments that may provide data storage functionality for one or more clients. Another example of a cloud computing environment is one in which processing, and other, services may be performed on behalf of one or more clients. Some example cloud computing environments in connection with which embodiments of the invention may be employed include, but are not limited to, Microsoft Azure, Amazon AWS, Dell EMC Cloud Storage Services, and Google Cloud. More generally however, the scope of the invention is not limited to employment of any particular type or implementation of cloud computing environment.

In addition to the cloud environment, the operating environment may also include one or more clients that are capable of collecting, modifying, and creating, data. As such, a particular client may employ, or otherwise be associated with, one or more instances of each of one or more applications that perform such operations with respect to data. Such clients may comprise physical machines, containers, or virtual machines (VMs).

Particularly, devices in the operating environment may take the form of software, physical machines, containers, or VMs, or any combination of these, though no particular device implementation or configuration is required for any embodiment. Similarly, data protection system components such as databases, servers, storage volumes (LUNs), storage disks, services, and the like, for example, may likewise take the form of software, physical machines, containers, or virtual machines (VM), though no particular component implementation is required for any embodiment.

As used herein, the term ‘data’ is intended to be broad in scope. Example embodiments of the invention are applicable to any system capable of storing and handling various types of objects or other data, in analog, digital, or other form.

It is noted with respect to the disclosed methods, that any operation(s) of any of these methods, may be performed in response to, as a result of, and/or, based upon, the performance of any preceding operation(s). Correspondingly, performance of one or more operations, for example, may be a predicate or trigger to subsequent performance of one or more additional operations. Thus, for example, the various operations that may make up a method may be linked together or otherwise associated with each other by way of relations such as the examples just noted. Finally, and while it is not required, the individual operations that make up the various example methods disclosed herein are, in some embodiments, performed in the specific sequence recited in those examples. In other embodiments, the individual operations that make up a disclosed method may be performed in a sequence other than the specific sequence recited.

Following are some further example embodiments of the invention. These are presented only by way of example and are not intended to limit the scope of the invention in any way.

Embodiment 1. A method comprising: determining a global divergence threshold for input data based on sample data, a compressor, and a tolerance parameter, determining a relationship between a compression quality \hat{q}nd divergences generated using the sample data that is processed by a classifier and using perturbed sample data that is processed by the classifier, and determining a compression quality for the input data based on the global divergence threshold and the relationship, wherein the compressor is configured to compress the input data based on the compression quality.

Embodiment 2. The method of embodiment 1, wherein the global divergence threshold comprises a global KL (Kullback-Leibler) threshold.

Embodiment 3. The method of embodiment 1 and/or 2, further comprising determining an individual KL threshold for each sample in the sample data and each sample in the perturbed sample data.

Embodiment 4. The method of embodiment 1, 2, and/or 3, wherein an accuracy of the classifier is according to the tolerance parameter if a perturbation applied to the perturbed sample data satisfies: kl(f(xᵢ),f(ti))<L(X,f),i=1,2, . . . , n, wherein Lₖₗ is the global divergence threshold, X is the sample data, xᵢ is a sample included in the sample data, and xᵢ is a sample included in the perturbed data.

Embodiment 5. The method of embodiment 1, 2, 3, and/or 4, further wherein determining the global divergence threshold includes evaluating the sample data with the classifier and evaluating the perturbed sample data with the classifier, wherein the perturbed sample data has been compressed and decompressed prior to processing by the classifier.

Embodiment 6. The method of embodiment 1, 2, 3, 4, and/or 5, further comprising determining average KL divergences between classifying the original sample data with the classifier and classifying the decompressed perturbed sample data with the classifier for each of multiple compression quality values applied to the compressor.

Embodiment 7. The method of embodiment 1, 2, 3, 4, 5, and/or 6, wherein the relationship is defined as R(q)=Average (kl(f(xᵢ))f(\tilde{x}ᵢ), i=1,2, . . . n).

Embodiment 8. The method of embodiment 1, 2, 3, 4, 5, 6, and/or 7, wherein determining the compression quality includes selecting a compression quality that ensures that the global divergence threshold is satisfied or such that R(q)<Lₖₗ for all q>x.

Embodiment 9. The method of embodiment 1, 2, 3, 4, 5, 6, 7, and/or 8, further comprising compressing the input data based on the compression quality.

Embodiment 10. The method of embodiment 1, 2, 3, 4, 5, 6, 7, 8, and/or 9, further comprising dynamically adjusting the compression quality based on network conditions.

Embodiment 11. A system, comprising hardware and/or software, operable to perform any of the operations, methods, or processes, or any portion of any of these, disclosed herein.

Embodiment 12. A non-transitory storage medium having stored therein instructions that are executable by one or more hardware processors to perform operations comprising the operations of any one or more of embodiments 1-11.

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

As indicated above, embodiments within the scope of the present invention also include computer storage media, which are physical media for carrying or having computer-executable instructions or data structures stored thereon. Such computer storage media may be any available physical media that may be accessed by a general purpose or special purpose computer.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality of the invention. Combinations of the above should also be included within the scope of computer storage media. Such media are also examples of non-transitory storage media, and non-transitory storage media also embraces cloud-based storage systems and structures, although the scope of the invention is not limited to these examples of non-transitory storage media.

Computer-executable instructions comprise, for example, instructions and data which, when executed, cause a general purpose computer, special purpose computer, or special purpose processing device to perform a certain function or group of functions. As such, some embodiments of the invention may be downloadable to one or more systems or devices, for example, from a website, mesh topology, or other source. As well, the scope of the invention embraces any hardware system or device that comprises an instance of an application that comprises the disclosed executable instructions.

Although the subject matter has been described in language specific to structural features and/or methodological acts, it is to be understood that the subject matter defined in the appended claims is not necessarily limited to the specific features or acts described above. Rather, the specific features and acts disclosed herein are disclosed as example forms of implementing the claims.

As used herein, the term module, component, engine, service, client, agent, or the like may refer to software objects or routines that execute on the computing system. The different components, modules, engines, and services described herein may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments of the invention may be performed in client-server environments, whether network or local environments, or in any other suitable environment. Suitable operating environments for at least some embodiments of the invention include cloud computing environments where one or more of a client, server, or other machine may reside and operate in a cloud environment.

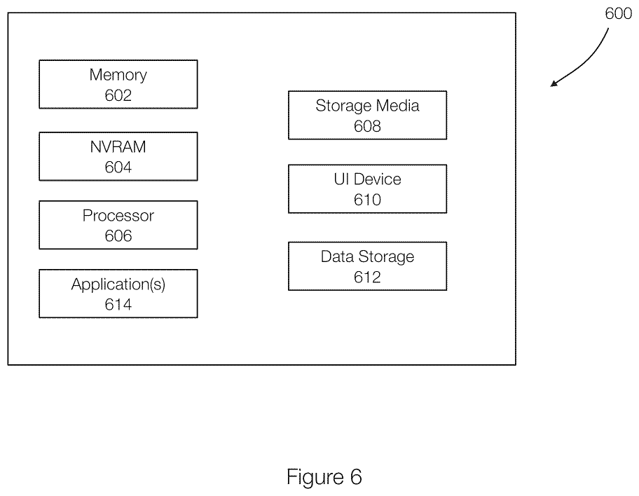

With reference briefly now to FIG. 6, any one or more of the entities disclosed, or implied, by the Figures and/or elsewhere herein, may take the form of, or include, or be implemented on, or hosted by, a physical computing device, one example of which is denoted at 700. As well, where any of the aforementioned elements comprise or consist of a virtual machine (VM), that VM may constitute a virtualization of any combination of the physical components disclosed in FIG. 7.

In the example of FIG. 7, the physical computing device 700 includes a memory 702 which may include one, some, or all, of random access memory (RAM), non-volatile memory (NVM) 704 such as NVRAM for example, read-only memory (ROM), and persistent memory, one or more hardware processors 706, non-transitory storage media 708, UI device 710, and data storage 712. One or more of the memory components 702 of the physical computing device 700 may take the form of solid state device (SSD) storage. As well, one or more applications 714 may be provided that comprise instructions executable by one or more hardware processors 716 to perform any of the operations, or portions thereof, disclosed herein.

The device 700 may also represent systems such as edge systems, cloud systems, gateways, or the like.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method comprising:
determining a global divergence threshold for input data based on sample data, a compressor, and a tolerance parameter;
determining a relationship between a compression quality \hat{q}nd divergences generated using the sample data that is processed by a classifier and using perturbed sample data that is processed by the classifier; and
determining a compression quality for the input data based on the global divergence threshold and the relationship, wherein the compressor is configured to compress the input data based on the compression quality.

2. The method of claim 1, wherein the global divergence threshold comprises a global KL (Kullback-Leibler) threshold.

3. The method of claim 2, further comprising determining an individual KL threshold for each sample in the sample data and each sample in the perturbed sample data.

4. The method of claim 3, wherein an accuracy of the classifier is determined according to the tolerance parameter if a perturbation applied to the perturbed sample data satisfies a relationship such that a divergence between results of the classifier applied to the sample data and results of the classifier applied to the perturbed data is smaller than the global divergence threshold for substantially all samples in the sample data.

5. The method of claim 1, wherein determining the global divergence threshold includes evaluating the sample data with the classifier and evaluating the perturbed sample data with the classifier, wherein the perturbed sample data has been compressed and decompressed prior to processing by the classifier.

6. The method of claim 1, further comprising determining average KL divergences between classifying the original sample data with the classifier and classifying the decompressed perturbed sample data with the classifier for each of multiple compression quality values applied to the compressor.

7. The method of claim 6, wherein the relationship is defined as
$$R ( q ) = Average ( kl ( f ( {x}_{i} ) , f ( {\tilde{x}}_{i} ) ) , i = 1 , 2 , … n ) .$$

8. The method of claim 7, wherein determining the compression quality includes selecting a compression quality that ensures that the global divergence threshold is satisfied or such that R(q)<Lₖₗ for all q>x.

9. The method of claim 1, further comprising compressing the input data based on the compression quality.

10. The method of claim 1, further comprising dynamically adjusting the compression quality based on network conditions.

11. A non-transitory storage medium having stored therein instructions that are executable by one or more hardware processors to perform operations comprising:
determining a global divergence threshold for input data based on sample data, a compressor, and a tolerance parameter;
determining a relationship between a compression quality \hat{q}nd divergences generated using the sample data that is processed by a classifier and using perturbed sample data that is processed by the classifier; and
determining a compression quality for the input data based on the global divergence threshold and the relationship, wherein the compressor is configured to compress the input data based on the compression quality.

12. The non-transitory storage medium of claim 11, wherein the global divergence threshold comprises a global KL (Kullback-Leibler) threshold.

13. The non-transitory storage medium of claim 12, further comprising determining an individual KL threshold for each sample in the sample data and each sample in the perturbed sample data.

14. The non-transitory storage medium of claim 13, wherein an accuracy of the classifier is determined according to the tolerance parameter if a perturbation applied to the perturbed sample data satisfies a relationship such that a divergence between results of the classifier applied to the sample data and results of the classifier applied to the perturbed data is smaller than the global divergence threshold for substantially all samples in the sample data.

15. The non-transitory storage medium of claim 11, further wherein determining the global divergence threshold includes evaluating the sample data with the classifier and evaluating the perturbed sample data with the classifier, wherein the perturbed sample data has been compressed and decompressed prior to processing by the classifier.

16. The non-transitory storage medium of claim 11, further comprising determining average KL divergences between classifying the original sample data with the classifier and classifying the decompressed perturbed sample data with the classifier for each of multiple compression quality values applied to the compressor.

17. The non-transitory storage medium of claim 16, wherein the relationship is defined as
$$R ( q ) = Average ( kl ( f ( {x}_{i} ) , f ( {\tilde{x}}_{i} ) ) , i = 1 , 2 , … n ) .$$

18. The non-transitory storage medium of claim 17, wherein determining the compression quality includes selecting a compression quality that ensures that the global divergence threshold is satisfied or such that R(q)<Lₖₗ for all q>x.

19. The non-transitory storage medium of claim 11, further comprising compressing the input data based on the compression quality.

20. The non-transitory storage medium of claim 11, further comprising dynamically adjusting the compression quality based on network conditions.
